(19) United States
(12) Patent Application Publication
(10) Pub. No.: US 2021/0371977 A1
(43) Pub. Date: Dec. 2, 2021

(54) SOLID MATERIAL CONTAINER AND SOLID MATERIAL PRODUCT IN WHICH SAID SOLID MATERIAL CONTAINER IS FILLED WITH A SOLID MATERIAL

(71) Applicant: L'Air Liquide, Société Anonyme pour l'Etude et I'Exploitation des Procédés Georges Claude, Paris (FR)

(72) Inventors: Toshiyuki NAKAGAWA, Hyogo (JP); Mikio GOTO, Tokyo (JP); Kazuma SUZUKI, Tsukuba (JP); Toru AOYAMA, Tsukuba (JP); Takashi KAMEOKA, Tsukuba (JP); Kazutaka YANAGITA, Tsukuba (JP)

(21) Appl. No.: 16/765,901

(22) PCT Filed: Nov. 13, 2018
(86) PCT No.: PCT/EP2018/081028

§ 371 Date: May 21, 2020

(30) Foreign Application Priority Data
Nov. 22, 2017 (JP) 2017-224920

(51) Int. Cl. C23C 16/448; B01J 7/00

(52) U.S. Cl. CPC C23C 16/4481; B01J 7/00

(57) ABSTRACT

A solid material container 1 which gasifies and supplies a solid material 25 contained therein has a carrier gas introduction pipe 11, a solid material discharge pipe 12, a metal outer unit 21, an inner unit 22 which is filled with the solid material 25 and in which at least those sections which are in contact with the solid material are made out of a nonmetal material, and a lid unit 23 in which at least those sections which are in contact with the solid material 25 are made out of a nonmetal material. The inner unit 22 and the lid unit 23 are contained inside the outer unit 21.

### CROSS REFERENCE TO RELATED APPLICATIONS

This application is a 371 of International PCT Application PCT/EP2018/081028, filed Nov. 13, 2018, which claims priority to Japanese Patent Application No. 2017-224920, filed Nov. 22, 2017, the entire contents of which are incorporated herein by reference.

### BACKGROUND

The present invention relates to a solid material container for supplying vapor of a semiconductor manufacturing material, e.g., a solid material for manufacturing a thin film, and a solid material product in which the solid material container is filled with the solid material.

As the semiconductor industry has advanced, there has been a demand for use of new precursor materials which might satisfy strict thin-film requirements. These materials are used for a wide range of purposes in thin-film deposition and machining of semiconductor products.

Examples in solid precursor materials include the constituent components for barrier layers, high-dielectric-constant/low-dielectric-constant insulation layers, metal electrode layers, connection layers, ferroelectric layers, and silicon nitride layers or silicon oxide layers. Additional examples of solid precursors include constituent components acting as dopants for compound semiconductors, and etching materials. Exemplary precursor materials include inorganic compounds and organic metal compounds of aluminum, barium, bismuth, chrome, cobalt, copper, gold, hafnium, indium, iridium, iron, lanthanum, lead, magnesium, molybdenum, nickel, niobium, platinum, ruthenium, silver, strontium, tantalum, titanium, tungsten, yttrium, and zirconium.

Since some of these new materials are in solid form at standard temperatures and pressures, they cannot be directly supplied into semiconductor film formation chambers in the manufacturing process.

In general, these materials have extremely high melting points and low vapor pressures, and must therefore be gasified or sublimated within a narrow range of temperatures and pressures before being supplied to the film formation chamber.

Moreover, materials with low impurity content must be supplied, in order to minimize damage and control performance of the films making up the semiconductor parts which are being formed.

Several techniques for gasifying and sublimating solid materials have been developed. For example, JP 2008-501507 A and JP 2011-509351 A propose methods for disposing a plurality of trays filled with solid materials horizontally inside a solid material container.

The solid material containers disclosed in JP 2008-501507 A and JP 2011-509351 A are generally made out of metal, such as stainless steel. Since solid materials often have low vapor pressure, they are often used while heating the solid material container. Heating a solid material in a metal solid material container causes metal contamination of the solid material caused by the material of the solid material container (i.e., admixture of metal impurities in the solid material), which risks being a cause of metal contamination in the thin films which are formed.

JP 2008-501507 A discloses that the solid material container and/or the internal structure of the solid material container can be made out of ceramic or another nonmetal material.

However, if the solid material container or the internal structure thereof is made out of ceramic, the mechanical strength is weak, making it substantially impossible to transport or use. If a ceramic container or part breaks, the broken pieces produce particles, which creates the risk of the semiconductor parts which are manufactured not functioning. It is also possible for the solid material container to become unusable due to breakage.

In order to improve the mechanical strength, one possibility is to make the ceramic material thicker, but this is unrealistic, because the increased volume renders the container inconvenient to use, and also because this renders the container unsuitable for a method of use in which it is heated during since, since the heat conductivity falls.

Furthermore, a complicated internal structure of the solid material container would make machining of the ceramic material extremely difficult.

Incidentally, JP 2008-501507 A discloses a structure having a tray section filled with solid material in the solid material container. However, the tray section does not have a lid.

Therefore, during transportation or in the event of shocks undergone by the solid material container, the solid material filling the tray would fall out of the tray. Any solid material falling out of the tray would come in contact with the internal side walls of the solid material container, so if the internal side walls were made out of metal, the solid material would risk becoming contaminated by the metal material of the internal side walls.

Furthermore, if the vapor of the solid material filling the solid material container is supplied while the solid material container is being heated, the gasified solid material will recondense on the ceiling of the solid material container. There is a possibility that the temperature of the ceiling of the solid material container is lower than in the middle of the solid material container, so any solid material which has gasified in the middle of the solid material container will recondense due to the drop in temperature on the ceiling. When this happens, if the ceiling is made out of metal, any solid material which recondenses and is eluted will come in contact with the metal material of the ceiling and be contaminated.

Due to this background, development of a solid material container is desired which is capable of minimizing admixture of metal impurities into solid material caused by the material of the solid material container, using a simple method and configuration.

### SUMMARY

### Invention 1

A solid material container according to the present invention is a solid material container for gasifying and supplying a solid material contained therein, comprising a solid material discharge pipe that discharges vapor of the solid material out of the solid material container, a metal outer unit, an inner unit which is filled with the solid material and in which at least those sections in contact with the solid material are made out of a nonmetal material, and a lid unit which is disposed on top of the inner unit, and in which at least those sections in contact with the solid material are made out of a nonmetal material, wherein the inner unit and the lid unit are contained inside the outer unit.

The solid material container may further have carrier gas introduction pipe which introduces a carrier gas into the solid material container. The carrier gas introduction pipe may be made out of metal, may be made out of a nonmetal material, and may have a nonmetal surface layer on a metal material in sections which come in contact with the solid material.

If the carrier gas introduction pipe is made out of metal, the inner unit may be provided with a pipe cover unit in which at least those sections of the carrier gas pipe which come in contact with the solid material are made out of a nonmetal material.

The solid material container according to the present invention has a metal outer unit, and therefore does not suffer breaking, cracking, or other damage due to external shocks thanks to its good mechanical strength. Therefore, the solid material container can be used safely during transportation and when using solid materials.

Furthermore, solid material containers are often used while being heated using heaters, etc., and if the outer unit is a metal container, it will have good heat conduction, allowing for efficient heating. Furthermore, the inner section can be made out of a nonmetal material having thermal conductivity, or a metal material having a surface layer which is a nonmetal material. By endowing the outer unit with mechanical strength, the inner unit can be made thinner, and the total heat conductivity of the outer unit and the inner unit can be increased.

By filling the metal outer unit with the solid material directly, there is a risk of the solid material being contaminated by the metal. This is because particles produced by the metal sections can get mixed in, and metal sections can become corroded, producing corrosion products which can get mixed in. In particular, if the solid material is a chloride, a fluoride, or an acid (e.g., AlCl₃, HfCl₄, WCl₆, WCl₅, NbF₅, TiF₄, XeF₂, or carboxylic acid anhydride, etc.), production of corrosion products becomes notable due to these reacting with the metal and corroding it. Production of particles and corrosion products is a cause of metal contamination in the solid material, and is a cause of metal corrosion of the thin film made using the solid material. If the solid material container is heated during use, the corrosion is promoted, and the damage to the thin film due to the metal contamination is even more notable.

The nonmetal material in the inner unit, lid unit, and pipe cover unit of the solid material container according to the present invention is any material not consisting only of metal elements, e.g., a material in which the ratio of metal elements is 95 wt. % or less. For example, the material may be a ceramic material, glass, a polymer material, a metal nitride containing material, a metal oxide containing material, a carbon containing material, or quartz, according to the temperature of use of a solid material container 1, properties of a solid material 25, and/or the process using the vapor of the solid material 25 discharged from the solid material container. The entire inner unit, the entire lid unit, or the entire pipe cover unit may be made out of a nonmetal material, or those sections of the inner unit, the lid unit, or the pipe cover unit which are in contact with the solid material may be made out of a nonmetal material. It is also possible for those sections of the inner unit, the lid unit, and the pipe cover unit, which are made out of metal, which come in contact with the solid material to have a surface layer which is made out of a nonmetal material.

Metal materials on which a surface layer is formed which is made out of a nonmetal material include, but are not limited to, stainless steel, aluminum, aluminum alloys, copper, and copper alloys, for example. Furthermore, examples of products in common circulation are Inconel™, Monel™, and Hastelloy™, but these are not limitations. Examples of nonmetal materials constituting the surface layer include, but are not limited to, polymer materials, metal nitride containing materials (e.g., TaN, TiN, TiAlN, WN, GaN, TaCN, TiCN, TaSiN, and TiSiN), metal oxide containing materials (e.g., HfO₂, Ta₂O₅, ZrO₂, TiO₂, Al₂O₃, barium strontium titanate, and yttrium oxide), ceramic materials, carbon containing materials (e.g., DLC (diamond-like carbon) and SiC), or other materials including any combination of these materials. It is also possible to alternately laminate a plurality of materials.

If the entirety of the inner unit, the lid unit, or the pipe cover unit of the solid material container according to the present invention is made out of a ceramic material, or if those sections of the inner unit, the lid unit, or the pipe cover unit which come in contact with the solid material are made out of a ceramic material, the ceramic material may be selected from alumina, zirconia, hafnia, barium titanate, hydroxyapatite, silicon carbide, silicon nitride, aluminum nitride, titanium nitride, titanium oxide, yttrium oxide, or fluorite, according to the usage temperature of the solid material container or the characteristics of the solid material, for example.

With the solid material container according to the present invention, the inner unit in which at least those sections which are in contact with the solid material are made out of a nonmetal material is placed inside the metal outer unit, the inner unit is filled with the solid material, the lid is disposed thereon, and the lid is closed. This way, the solid material filling the inner unit can be prevented from coming in contact with the metal outer unit in places corresponding to the bottom surface and side surfaces of the solid material container.

Furthermore, after the inner unit is filled with the solid material, the lid unit, in which at least those sections which are in contact with the solid material are made out of a nonmetal material, is disposed. This way, the solid material is prevented from coming in contact with the outer unit, which is made out of metal, in places corresponding to the top surface of the solid material container, or recondensing and being eluted. Furthermore, the solid material can be prevented from leaking out of the inner unit during transportation, etc., and coming in contact with the metal outer unit.

In the solid material container according to the present invention, a carrier gas is introduced and can accompany the vapor of the solid material, but it is also possible to discharge just the vapor of the solid material, without introducing a carrier gas, according to the characteristics of the solid material and the temperature and pressure, etc., at which the solid material is used.

Because the carrier gas is introduced into the solid material container, the solid material container may have a carrier gas introduction pipe for introducing the carrier gas.

The material of the carrier gas introduction pipe may be any material as long as it is inert to the carrier gas. Metal materials such as stainless steel, etc., are typically used. Accordingly, the solid material container according to the present invention may be provided with a pipe cover unit in which at least those sections which come in contact with the solid material are made out of a nonmetal material in order to prevent contact between the carrier gas introduction pipe and the solid material.

With this configuration, the solid material can be prevented from coming in contact with metal inside the solid material container, and metal contamination of the solid material can be minimized.

### Invention 2

The solid material container according to the present invention is such that protrusions are formed on the inside of the outer unit, and the bottom of the inner unit has an inner unit fitting section which removably fits into the outer unit on the projections.

When the inner unit, which has a smaller outer dimension than the inner dimension of the outer unit, is placed in the metal outer unit, the position of the inner unit could conceivably move inside the outer unit. Accordingly, the solid material container of the present invention has projections formed in the outer unit, and the inner unit has an inner unit fitting section for removably fitting the bottom of the inner unit onto said projections. By fitting the inner unit bottom section into the outer unit, the position of the inner unit inside the outer unit is fixed. Therefore, the outer unit and the inner unit can be prevented from bumping into each other during transportation, etc., and the inner unit can be prevented from breaking. By preventing the inner unit from breaking, it is possible to minimize the production of corrosion products due to any solid material leaking out of the inner unit coming in contact with the metal outer unit, or the production of particles from broken sections of the inner unit. If the inner unit has a nonmetal outer surface on top of a metal material, it is possible to minimize the phenomenon of peeling due to the surface layer bumping against the outer unit.

By making the inner unit fitting section removable from the outer unit and the protrusions, the outer unit and the inner unit can be separated, washed, and dried, etc. Conventionally, in order to prevent the inner unit from bumping against the inside of the outer unit, the entire inner unit was often made so as to be disposed snugly inside the outer unit. However, because the clearance between the inner unit and the outer unit would have to be made smaller in this case, advanced machining technology was required. High-precision machining is particular difficult when the solid material container is large. Moreover, the small clearance would create the problem of the inner unit not being able to be inserted smoothly into the outer unit. However, with the present invention, the inner unit and the outer unit are fixed by being fitted together, making it possible to make the clearance between the inner unit and the outer unit relatively large, which makes machining easier and can make insertion smoother.

Nonmetal materials break easily due to thermal expansion during heating. The risk of breakage also grows after repeated heating and cooling. However, with the present invention, which makes it possible to make the clearance larger, the phenomenon of breakage due to contact and bumping between nonmetal and metal materials due to thermal expansion can be minimized.

The size of the clearance is preferably a size which takes into consideration the coefficient of thermal expansion at the temperatures at which the metal and nonmetal materials employed are used. For example, it is preferable to use a clearance which is greater than the maximum dimension of expansion for a particular coefficient of thermal expansion.

### Invention 3

The lid unit of the solid material container according to the present invention has one or more top ventilation sections through which the vapor of the solid material passes.

With the present invention, the solid material, which has been gasified and become a vapor, is discharged out of the solid material container with the carrier gas via the top ventilation sections.

The top ventilation sections may be any shape as long as gas can pass through them; they may be circular holes or slit-shaped, and a plurality of holes and slits may be disposed. By disposing the top ventilation sections uniformly in the lid unit, the flow of the solid material vapor inside the inner unit can be made uniform. By making the flow of the solid material vapor uniform, collection of the solid material inside the inner unit can be prevented, and the concentration of the solid material vapor which is discharged can be kept uniform. For example, if the top ventilation units are in a showerhead shape in which a plurality of circular holes are disposed, the solid material vapor is uniformly discharged from the plurality of holes in a showerhead arrangement. After the solid material vapor is discharged from the top ventilation units, the solid material vapor does come in contact with the top of the metal outer unit but does not directly come in contact in solid form, and therefore the risk of metal contamination caused by the solid material coming in contact with the metal material is thought to be small.

### Invention 4

The lid unit of the solid material container according to the present invention has a lid fitting section which removably fits onto the top of the inner unit.

With the present invention, the top of the inner unit and the lid unit fit together and are fixed together in the lid unit fitting section, and therefore the inner unit and the lid unit can be prevented from becoming misaligned. Accordingly, the phenomenon of the solid material leaking through gaps created by misalignment of the inner unit and the lid unit and coming in contact with the metal outer unit, resulting in contamination of the solid material by metal, can be prevented.

Furthermore, because the lid unit is affixed to the inner unit, the phenomenon of the lid unit bumping against the inner unit or the outer unit and breaking can be minimized.

### Invention 5

The inner unit of the solid material container according to the present invention has inner unit side walls and an inner unit bottom section, and the inner unit side walls have a bottom section fitting section which removably fits onto the inner unit bottom section.

In the inner unit, the side wall and the bottom unit may be a single unit, but it is also possible to make the inner unit side walls and the inner unit bottom section separate members and configure the inner unit by removably fitting these together. If the inner unit side walls and the inner unit bottom section are manufactured as separate members, manufacturing and machining are easier than if manufacturing the inner unit as a single member. Moreover, the phenomenon of the solid material leaking through gaps created by misalignment of the side walls and the inner unit bottom section and coming in contact with the metal outer unit, resulting in contamination of the solid material by metal, can be prevented. Furthermore, because the inner unit side walls are affixed to the inner unit bottom section, if the inner unit bottom section is affixed to the outer unit in the inner unit fitting section, the phenomenon of the inner unit side walls bumping against the outer unit and breaking can be minimized.

### Invention 6

The solid material container according to the present invention is such that an inner section bottom plate is disposed in the inner unit bottom section, and the inner unit bottom plate has one or more bottom ventilation sections through which the carrier gas passes.

The inner unit bottom plate is disposed so as to disperse the carrier gas and cause the carrier gas to come into contact with the solid material uniformly. It is preferable for at least those sections of the inner unit bottom plate which come in contact with the solid material to be made out of a nonmetal material. The entire inner unit bottom plate may be made out of a nonmetal material, and may also have a surface layer in which only those sections of the inner unit bottom plate which come in contact with the solid material are made out of a nonmetal material. The carrier gas introduction pipe is inserted into the inner unit, and extends all the way to under the inner unit bottom plate disposed in the inner unit bottom section. In other words, a carrier gas outlet of the carrier gas introduction pipe opens under the inner unit bottom plate. The carrier gas is fed from the carrier gas outlet in the carrier gas introduction pipe to the bottom of the inner unit bottom plate, passes through the bottom ventilation sections in the inner unit bottom plate, moves to the top of the inner unit bottom plate, and comes in contact with the solid material which fills the inside of the inner unit, which is above the inner unit bottom plate.

The bottom ventilation sections may be any shape as long as gas can pass through them; they may be circular holes or slit-shaped, and a plurality of holes and slits may be disposed. By disposing the bottom ventilation sections uniformly in the inner unit bottom plate, the flow of the carrier gas inside the inner unit can be made uniform. By making the flow of the carrier gas uniform, the carrier gas comes in contact with the solid material uniformly, which can prevent the solid material from collecting inside the inner unit and keep the concentration of the solid material vapor discharged from the inner unit uniform. For example, if the bottom ventilation units are in a showerhead shape in which a plurality of circular holes are disposed, the solid material vapor is uniformly discharged from the plurality of holes in a showerhead arrangement.

### Invention 7

The inner unit side walls of the solid material container according to the present invention have plate section top surface fitting sections which removably fit onto a bottom plate top surface section disposed on the top surface of the inner unit bottom plate, and the inner unit bottom section has a plate section bottom surface fitting section which removably fits with a bottom plate bottom surface fitting section disposed on a bottom surface of the inner unit bottom plate.

The inner unit bottom plate can be disposed on the bottom section of the inner unit, in which the inner unit side walls and the inner unit bottom section are a single unit, or the inner unit side walls, the inner unit bottom section, and the inner unit bottom plate can be made individual members and removably fitted together to configure the inner unit. The inner unit bottom plate is disposed on and fitted onto the inner unit, and the inner unit side walls are disposed on and fitted onto the inner unit bottom plate, and thus can the inner unit be configured.

If the inner unit side walls, the inner unit bottom section, and the inner unit bottom plate are manufactured as separate members, manufacturing and machining are easier than if manufacturing everything as a single member. Because the bottom ventilation sections are open in the inner unit bottom plate, it is conceivable that the solid material might fall through the bottom ventilation sections onto the inner unit bottom section, but if it does fall, the solid material merely comes in contact with the inner unit bottom section, and does not come in contact with the metal outer unit.

Because the inner unit side walls and the inner unit bottom plate, or the inner unit bottom plate and the inner unit bottom section are fitted together, it is possible to minimize the phenomenon of the solid material leaking out through gaps caused by misalignment thereof and coming in contact with the metal outer unit, the solid material thereby being contaminated by the metal.

Furthermore, because the inner unit side walls are affixed to the inner unit bottom section and the inner unit bottom plate is affixed to the inner unit bottom section, if the inner unit bottom section is affixed to the outer unit in the inner unit fitting section, the phenomenon of the inner unit side walls bumping against the outer unit and breaking can be minimized.

### Invention 8

The inner unit of the solid material container according to the present invention is configured by a plurality of trays which are disposed at fixed intervals vertically, which are filled with the solid material, and at least those sections thereof which come in contact with the solid material are made out of a nonmetal material.

By disposing the plurality of trays filled with the solid material vertically, the carrier gas comes in contact with the surface of the solid material filling the plurality of trays, making it possible to increase the area of contact between the carrier gas and the solid material. Increasing the area of contact with the carrier gas can prevent a drop in vapor concentration of the solid material in the carrier gas caused by insufficient area of contact. The drop in the temperature of the solid material surface due to escape of gasification heat is particularly notable when gasifying the solid material for long periods of time or if the solid material gasification quantity is large. If the temperature of the surface of the solid material falls, the vapor pressure of the solid material where the temperature has fallen also falls, which makes it harder for the solid material to gasify, which in turn causes the concentration of the solid material vapor in the carrier gas discharged from the solid material container to fall and become unstable. In such cases, too, if the area of contact with the carrier gas is increased by disposing a plurality of trays, the solid material vapor can be discharged with a stable concentration, without the temperature of the surface of the solid material falling.

### Invention 9

The plurality of trays in the solid material container according to the present invention in which at least those sections which are in contact with the solid material are made out of a nonmetal material comprise at least one first tray which has an outer supporting section on side edges thereof and is smaller than the inner dimension of the outer unit, and at least one second tray, which has an inner supporting section in a central section thereof and is smaller than the outer dimension of the first tray for forming an outer flow path.

The first tray is disposed so as to form an overlapping vertical stack with a neighboring second tray, and a fluid flow path is provided between the first tray and the second tray passing through the outer flow path.

With the present invention, the plurality of trays are disposed such that the first tray and the second tray are overlapping and stacked. If there is a plurality of first trays, they are disposed such that the second tray is sandwiched between one of the first trays and another one of the first trays stacked on top of said first tray. Between the first tray and the second tray, which is smaller than the outer dimension of the first tray is the outer flow path through which passes the solid material vapor accompanied by the carrier gas. The carrier gas which passes over the first tray while coming in contact with the surface of the solid material filling the first tray flows into the second tray through the outer flow path and comes in contact with the surface of the solid material filling the second tray. This arrangement makes it possible for the carrier gas which is introduced into the inner unit to pass through the plurality of trays making up the inner section in order and come in contact with the solid material filling each of the trays. As a result, the area of contact between the surface of the solid material and the carrier gas increases, making it possible to discharge the solid material vapor with a stable concentration.

It is possible for one of the first trays and one of the second trays to be provided, but it is also possible for a plurality of the first trays and a plurality of the second trays to be provided. The number of the first trays and the number of the second trays may be the same, or there may be one more or one less of the first trays than the second trays.

### Invention 10

The first tray of the solid material container according to the present invention has an outer supporting section top fitting section provided to the top of the outer supporting section, and an outer supporting section bottom fitting section provided to the bottom of the outer supporting section.

The second tray has an inner supporting section top fitting section provided to the top of the inner supporting section, and an inner supporting section bottom fitting section provided to the bottom of the inner supporting section.

The outer supporting section top fitting section of at least one of the first trays is removably fitted so as to be stacked on the outer supporting section bottom fitting section of at least one of the vertically neighboring first trays.

The inner supporting section top fitting section of at least one of the first trays is removably fitted so as to be stacked on the inner supporting section bottom fitting section of at least one of the vertically neighboring first trays.

With the present invention, if one of the first trays is disposed so as to be stacked on another of the first trays, the outer supporting section top fitting section of the lower first tray is removably fitted onto the outer supporting section bottom fitting section of the top first tray, the top first tray and the bottom first tray thus being fixed together.

Similarly, if one of the second trays is disposed so as to be stacked on another of the second trays, the inner supporting section top fitting section of the lower second tray is removably fitted onto the inner supporting section bottom fitting section of the top second tray, the top second tray and the bottom second tray thus being fixed together.

Thus, by fitting the outer supporting section of one of the first trays onto the outer supporting section of another of the first trays so as to form a stack, the outer supporting sections are disposed without any gaps vertically. Accordingly, the carrier gas flowing onto the first tray flows through the outer flow path onto the second tray, without leaking out of the outer supporting sections towards the outer container. By fitting the outer supporting sections together, no carrier gas flows into any gaps between the outer supporting sections and the outer unit. Therefore, it is possible to minimize the carrier gas flowing between the outer unit and the outer supporting sections without coming in contact with the solid material and being discharged towards the back of the solid material container without being accompanied by the solid material vapor (or without sufficient solid material vapor accompanying it).

Similarly, by fitting the inner supporting section of one of the second trays onto the inner supporting section of another of the second trays so as to form a stack, the inner supporting sections are disposed without any gaps vertically. A pillar-shaped space can be provided to the center of the inner supporting sections. By disposing the inner supporting sections in this manner and disposing the carrier gas introduction pipe in the pillar-shaped space, the stacked inner supporting sections can form the pipe cover unit.

### Invention 11

The nonmetal material in the solid material container according to the present invention may be at least one material selected from the group consisting of ceramic materials, glass, polymer materials, metal nitride containing materials, metal oxide containing materials, carbon containing materials, and quartz.

### Invention 12

The ceramic material may be at least one material selected from the group consisting of alumina, zirconia, barium titanate, hydroxyapatite, silicon carbide, silicon nitride, aluminum nitride, titanium nitride, titanium oxide, yttrium oxide, and fluorite.

With the present invention, metal contamination of the solid material can be minimized by using a nonmetal material in the inner unit, the lid unit, the inner unit side walls, the inner unit bottom section, the inner unit bottom plate, the pipe cover section, and the trays. The solid material container is sometimes used at room temperature, and is sometimes heated during use. Therefore, a material which is selected from the group consisting of a ceramic material, glass, a polymer material, a metal nitride containing material, a metal oxide containing material, a carbon containing material, and quartz, which can be used at temperatures from room temperature to no greater than 400° C. is preferable. A material with thermal conductivity is preferable in order to efficiently conduct heat to the solid material when heated during use. Even if a material with low heat conductivity is used, the material can be made thin, thereby ensuring the thermal conductivity of the solid material container overall.

### Invention 13

The inner unit, the lid unit, the inner unit side walls, the inner unit bottom section, the inner unit bottom plate, and/or the trays in the solid material container according to the present invention may have a surface layer made out of a nonmetal material on at least part of the surface of a metal material. It is also possible for all metal surfaces to have a surface layer which is made out of a nonmetal material. It is also possible for those sections of all the metal surfaces which are in contact with the solid material to have a surface layer which is made out of a nonmetal material. Metal materials having a surface layer which is made out of a nonmetal material include, but are not limited to, stainless steel, aluminum, aluminum alloys, copper, and copper alloys, for example. Furthermore, examples of products in common circulation include, but are not limited to, Inconel™, Monel™, and Hastelloy™.

Examples of nonmetal materials constituting the surface layer may be any material other than a metal material, and include polymer materials, metal nitride containing materials (e.g., TaN, TiN, TiAlN, WN, GaN, TaCN, TiCN, TaSiN, and TiSiNO, metal oxide containing materials (e.g., HfO₂, Ta₂O₅, ZrO₂, TiO₂, Al₂O₃, barium strontium titanate, and yttrium oxide), ceramic materials, carbon containing materials (e.g., DLC (diamond-like carbon) and SiC), SiO₂, or other materials including any combination of these materials. It is also possible to alternately laminate several materials.

The thickness of the nonmetal material covering the metal may be, for example, in the range of 5 nm to 1000 nm, preferably in the range of 50 nm to 500 nm, and more preferably in the range from 100 nm to 300 nm, according to the characteristics of the metal and nonmetal materials, the conditions of use, and so on. If a plurality of materials are alternatingly laminated, the thicknesses of each may be in the range of 2 nm to 10 nm. The thickness of a layer of one material may be the same as or different to the thickness of a layer of another material. The thickness of the overall covering film after lamination may be in the range of 50 nm to 500 nm.

A material having greater thermal conductivity at 20° C. than stainless steel is preferable as the nonmetal material used in the inner unit, the lid unit, the inner unit side walls, the inner unit bottom section, the inner unit bottom plate, and the trays in the solid material container according to the present invention. By using a material with good thermal conductivity, conduction of heat from the outer unit to the solid material filling the inner unit is promoted, and the solid material in the inner unit located relatively near the outer unit and the solid material located farther away from the outer unit are heated more uniformly.

The thermal conductivity of stainless steel is 18 W/m·K, and therefore a nonmetal material having thermal conductivity greater than 18 W/m·K is preferable, and a nonmetal material having thermal conductivity greater than 40 W/m·K is even more preferable. Preferable examples of nonmetal materials having higher heat conductivity than stainless steel include alumina, aluminum nitride, silicon carbide, and silicon nitride, although aluminum nitride and silicon carbide are more preferable. If a material with high thermal conductivity is used and the solid material container is heated, heat is transmitted faster to the solid material in the inner unit. As a result, if temperature adjustment is done according to the amount of solid material vapor that needs to be supplied, the actual amount of solid material vapor discharged from the solid material container can be controlled with greater precision.

When selecting a nonmetal material or a ceramic material which is a nonmetal material, it is also possible to select a nonmetal material containing an element making up the solid material filling the inner unit. In this case, even if the element contained in the nonmetal material comes in contact with the solid material and thereby becomes included in the solid material, it is an element which is already contained in the solid material, so it does not become a contaminant.

For example, if the solid material is aluminum chloride, alumina, which is a ceramic material, can be used as the nonmetal material. In this case, even if the aluminum element originating in the alumina enters the aluminum chloride, it is indistinguishable from the aluminum in the aluminum chloride and does not become an impurity.

### Invention 14

The present invention is also a solid material product in which a solid material fills the solid material container.

The solid material may be a precursor used in depositing a semiconductor layer. The solid material may be the precursor itself, or the solid material carried on a carrier body such as beads, etc. The solid material may be in a solid state when being filled, it may be a solid material when the solid material container is being transported, and it may be in a liquid state when being filled or when being heated after being filled. There is no particular limitation on the solid material, which may be a material including a compound selected from the group consisting of an organic compound, an organic metal compound, a metal halogen compound, and mixtures of these. It may be AlCl₃, HfCl₄, WCl₆, WCl₅, NbF₅, TiF₄, XeF₂, or carboxylic acid anhydride, for example. The solid material may directly fill the solid material when connected to the semiconductor device. The solid material may fill the solid material container after the solid material container has been removed from the semiconductor device.

With the present invention, solid material vapor with little metal contamination can be supplied. With the present invention, metal contamination of solid material caused by metal material sections of the solid material container can be reduced, making it possible to supply solid material vapor with little metal contamination.

### BRIEF DESCRIPTION OF THE DRAWINGS

For a further understanding of the nature and objects for the present invention, reference should be made to the following detailed description, taken in conjunction with the accompanying drawings, in which like elements are given the same or analogous reference numbers and wherein:

FIG. 1 is a view showing an example of a configuration of a solid material container.

FIG. 2 is a view showing an example of a configuration of a solid material container.

FIG. 3 is a view showing an example of a configuration of a lid unit of the solid material container.

FIG. 4 is a view showing an example of a configuration of a lid unit of the solid material container.

FIG. 5 is a view showing an example of a configuration of a solid material container.

FIG. 6 is a view showing an example of a configuration of a solid material container.

FIG. 7 is a view showing an example of a configuration of a solid material container.

FIG. 8 is a view showing an example of a configuration of a solid material container.

FIG. 9 is a view showing an example of a configuration of a solid material container.

FIG. 10 is a view of an example of a configuration of a first tray and a second tray; and

FIG. 11 is a view showing an example of a configuration of a solid material container.

### DESCRIPTION OF PREFERRED EMBODIMENTS

Several embodiments of the present invention are described below. The embodiments described below describe examples of the present invention. The present invention is not limited in any way to the following embodiments, and includes variations implemented without departing from the gist of the present invention. Note that all the configurations described below are not necessarily essential configurations of the present invention.

### Embodiment 1

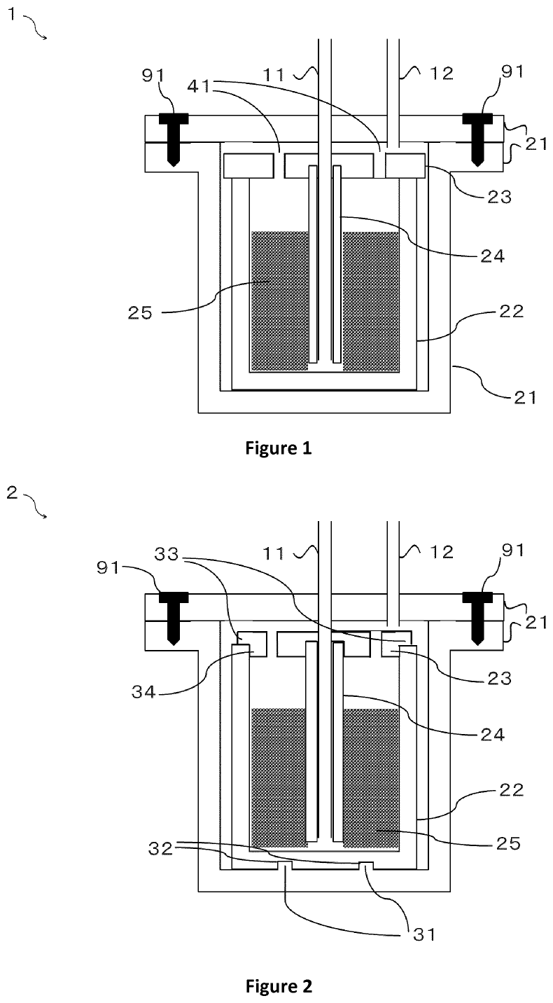

A solid material container 1 according to Embodiment 1 is described below, with reference to FIG. 1. The solid material container 1 is a solid material container for gasifying and supplying a solid material 25 contained therein.

The solid material container 1 has a carrier gas introduction pipe 11 which introduces a carrier gas into the solid material container 1, a solid material discharge pipe 12 which discharges vapor of the solid material 25 out of the solid material container 1, a metal outer unit 21, an inner unit 22 which is filled with the solid material 25 and in which at least those sections which are in contact with the solid material 25 are made out of a nonmetal material, and a lid unit 23 which is disposed on top of the inner unit 22 and in which at least those sections which are in contact with the solid material 25 are made out of a nonmetal material.

There is a clearance of about 1 mm between the side surfaces of the inner unit 22 and the outer unit 21, but the clearance may have any width. It is possible to provide a clearance which takes into account thermal expansion of the materials used in the inner unit 22 and the outer unit 21 at the temperature at which the solid material container 1 is used. If there is no thermal expansion to take into account, then it is also possible for there to be no clearance.

The vapor of the solid material 25 may be discharged from the solid material container 1 just as vapor by applying vacuum depressurization after the solid material container 1, or a carrier gas may be introduced into the solid material container 1 and the vapor of the solid material 25 may be discharged accompanied by the carrier gas.

The inner unit 22 is provided with a pipe cover unit 24 which is disposed around the carrier gas introduction pipe 11 and in which at least those sections which come in contact with the solid material 25 are made out of a nonmetal material.

If no carrier gas is introduced, the carrier gas introduction pipe 11 and the pipe cover unit 24 may not be provided.

The inner unit 22, the lid unit 23, and the pipe cover unit 24 are contained inside the outer unit 21.

Note that in this specification, the inner unit 22 includes a section where the solid material 25 fills the inner unit 22 and a space where the inner unit 22 is not filled with the solid material 25, and the outer unit 21 includes a section where the inner unit is contained, and a space where the inner unit 22 is not contained.

In the specification, the nonmetal material is any metal other than metals constituted solely by metal elements, namely a material in which the ratio of metal elements is 95 wt. % or less.

The metal outer unit 21 need only have a volume capable of containing the inner unit 22, and may be cylindrical or cubed. The outer unit 21 is made out of metal. The carrier gas introduction pipe 11 and the solid material discharge pipe 12 need only be pipes which allow gas to pass therethrough, and may be made out of metal.

If the outer unit 21, the carrier gas introduction pipe 11 and the solid material discharge pipe 12 are made out of metal, they may be made out of, but not limited to, stainless steel, aluminum, aluminum alloys, copper, or copper alloys, for example. Examples of products in common circulation include, but are not limited to, Inconel™, Monel™, and Hastelloy™.

The solid material 25 may be a precursor used in depositing a semiconductor layer. The solid material 25 may be the precursor itself, or the solid material 25 carried on a carrier body such as beads, etc. The solid material 25 may be in a solid state when being filled, it may be a solid material 25 when the solid material container 1 is being transported, and it may be in a liquid state when being filled or when being heated after being filled. There is no particular limitation on the solid material 25, which may be a material including a compound selected from the group consisting of an organic compound, an organic metal compound, a metal halide, and mixtures of these. It may be AlCl₃, HfCl₄, WCl₆, WCl₅, NbF₅, TiF₄, XeF₂, or carboxylic acid anhydride, for example.

The solid material product is obtained by filling the solid material container 1 with the solid material 25.

The carrier gas is not limited to any particular gas, and may be nitrogen, argon, helium, dry air, or hydrogen, or a combination thereof. An inert gas which does not cause a chemical reaction with the solid material is selected.

The inner unit 22 has a volume capable of being contained in the outer unit 21, and is the section where the solid material 25 can be filled. The inner unit 22 has a bottom section and side surfaces, and an opening through which the solid material 25 is filled. In the inner unit 22 shown in FIG. 1 the bottom section and the side surfaces are formed as a single unit, but it is also possible to dispose the bottom section and the side surfaces of the inner unit separately but without gaps therebetween, and adhere the separate bottom section and the side surfaces together.

It is preferable for at least those sections of the inner unit 22 which come in contact with the solid material 25 to be made out of a nonmetal material. The entire inner unit 22 may be made out of a nonmetal material, and may also have a surface layer in which only those sections of the inner unit 22 which come in contact with the solid material are made out of a nonmetal material. The surface layer need only be formed so as to cover at least part of the metal surface. The surface layer may be formed by depositing, applying, adhering, or spraying a nonmetal material onto the metal surface, for example, although this is not a limitation.

The lid unit 23 is disposed so as to prevent the solid material 25 filling the inner unit 22 from coming in contact with the metal outer unit 21 by covering the opening on the top of the inner unit 22. If the inner unit 22 is cylindrical, the lid unit 23 is disk-shaped.

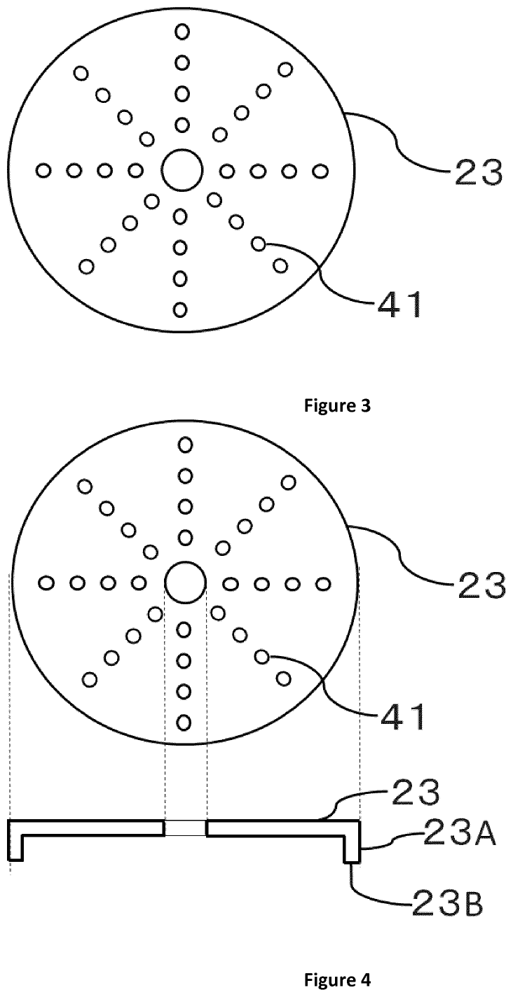

One or more upper ventilation sections 41 through which the vapor of the solid material 25 passes are disposed in the lid unit 23. The vapor of the solid material 25 may be accompanied by a carrier gas. The upper ventilation sections 41 may be any shape through which gas can pass, such as slit-shaped or in the shape of cylindrical holes. As shown in FIG. 3, there may be a showerhead arrangement in which a plurality of cylindrical holes are arranged a predetermined intervals.

The lid unit 23 may be a flat disk as shown in FIG. 3, or it may be Petri-dish-shaped, with a raised surrounding edge 23A as shown in FIG. 4. If it is Petri-dish-shaped, then it is possible for a fitting section (not shown in the drawings) to be formed on a bottom edge 23B of the surrounding edge 23A of the lid unit 23 allowing removable fitting with the top of the inner unit 22.

The pipe cover unit 24 may be disposed so as to cover the metal sections of the carrier gas introduction pipe 11, being, for example, cylindrical as shown in FIG. 1, with the carrier gas introduction pipe 11 disposed so as to be contained inside the pipe cover unit 24.

If there is a great deal of fluctuation in the amount of the solid material vapor discharged from the solid material container 1 and it is desirable to increase the precision of the amount of solid material gasified relative to the heat input from the heater (not shown in the drawings) which heats the solid material container 1, or if it is desired to quickly heat or cool the solid material 25, the heat conductivity can be improved by making the nonmetal material silicon carbide, for example, which has good heat conductivity.

A nonmetal material which does not contain metal elements can be selected in order to reduce metal contamination of the solid material 25, by minimizing admixture of metal elements in the solid material 25. It is possible to select silicon carbide, silicon nitride, aluminum nitride, titanium nitride, titanium oxide, or glass, for example.

By selecting a nonmetal material containing the same element as the element contained in the solid material 25, it is possible to achieve a configuration in which even admixture of part of the nonmetal material in the solid material 25 would not result in an impurity. For example, if the solid material 25 is aluminum chloride, it is possible to select alumina as the nonmetal material. As another example, if the solid material 25 is zirconium chloride, it is possible to select zirconia as the nonmetal material. If the solid material 25 is hafnium chloride, it is possible to select hafnia as the nonmetal material. As yet another example, if the solid material 25 is amino silicon, it is possible to select silicon nitride as the nonmetal material. By combining solid materials with nonmetal materials in this way, the effect of any nonmetal material getting mixed into the solid material 25 as a metal impurity (reducing the purity of the solid material, metal contamination of a thin film formed using the solid material) can be reduced. The nonmetal material can be selected according to the requirements of the characteristics of the solid material 25, the heating temperature of the solid material container 1, and the process using the solid material 25. For example, if the process using the solid material 25 is a process which requires avoiding admixture of aluminum, then a material not containing any aluminum can be selected.

In the solid material container 1 shown in FIG. 1, the inner unit 22 is fitted into the outer unit 21 and the pipe cover unit 24 is disposed, after which the inner unit 22 is filled with the solid material 25 and then the lid unit 23 is fitted onto the inner unit 22. Thereafter, the lid of the outer unit 21, having the carrier gas introduction pipe 11 is closed. The carrier gas introduction pipe 11 is inserted into the pipe cover unit 24 at this point. The lid of the outer unit 21 may be secured with screws 91. The solid material product is obtained by filling the solid material container 1 with the solid material 25.

The carrier gas introduced through the carrier gas introduction pipe 11 is fed to the bottom section of the inner unit 22 through an outlet of the carrier gas introduction pipe 11. The carrier gas thus fed comes in contact with the solid material 25 filling the inner unit 22, passes through the upper ventilation sections 41 disposed in the lid unit 23 accompanied by the vapor of the solid material 25, and is discharged through the solid material discharge pipe 12.

The solid material 25 filling the inner unit 22 comes in contact only with the inner unit 22, the pipe cover unit 24, and the lid unit 23, which are made out of a nonmetal material while being filled into the solid material container 1, and does not come in contact with the carrier gas introduction pipe 11, the outer unit 21, or the solid material discharge pipe 12, which are made out of metal. Therefore, there is no risk of corrosion products being produced by a reaction between the metal material and the solid material 25 or any metal components originating in the metal material from getting mixed into the solid material 25, thereby making it possible to minimize metal contamination of the solid material 25.

### Embodiment 2

A solid material container 2 according to Embodiment 2 is described below, with reference to FIG. 2. Elements having the same reference numerals as in the solid material container 1 in Embodiment 1 perform the same functions, and therefore descriptions thereof are omitted.

The solid material container 2 according to Embodiment 2 has projections 31 formed on the bottom surface of the outer unit 21, and the bottom surface of the inner unit 22 has inner unit fitting sections 32 which removably fit with the outer unit 21 on the projections 31.

In FIG. 2, the projections 31 are formed on the bottom section of the inside of the outer unit 21, but they may also be formed on side surfaces of the inside of the outer unit 21. The projections 31 may be round or rectangular pillar-shaped protrusions formed on the inside of the outer unit 21, and they may be protrusions formed as a ring on the bottom section of the inside of the outer unit 21. The projections 31 may also be recesses formed on the inside of the outer unit 21.

The inner unit fitting sections 32 may be formed so as to removably fit onto the projections 31, and if the projections 31 are protrusions, then the inner unit fitting sections 32 may be recesses. If the projections 31 are recesses, then the inner unit fitting sections 32 may be protrusions.

The lid unit 23 of the solid material container 2 has a lid unit fitting section 33 which removably fits onto the top of the inner unit 22. There is no particular limitation on the shape of the fitting sections, but if the top of the inner unit 22 is convex, then the lid unit fitting section 33 may be made concave, so as to allow fitting therebetween. If the top of the inner unit 22 is concave, then the lid unit fitting section 33 may be formed so as to be convex, thereby allowing fitting therebetween. In FIG. 2, the center of the lid unit 23 is formed circularly thicker (reference numeral 34 in FIG. 2) around the inner edges of the cylindrical inner unit 22 and the outer edges of the lid unit 23 (reference numeral 33 in the drawing FIG. 2) are formed thinner, thereby forming the lid unit fitting section 33 and allowing fitting onto the top of the inner unit 22.

With the solid material container 2, the outer unit 21 and the inner unit 22 are secured by fitting onto the projections 31. Therefore, damage to the lid unit 23 or the pipe cover unit 24 due to the inner unit 22 shifting inside the outer unit 21 can be prevented. Moreover, the inner unit 22 can be prevented from being damaged due to the outer unit 21 and the inner unit 22 bumping into each other.

### Embodiment 3

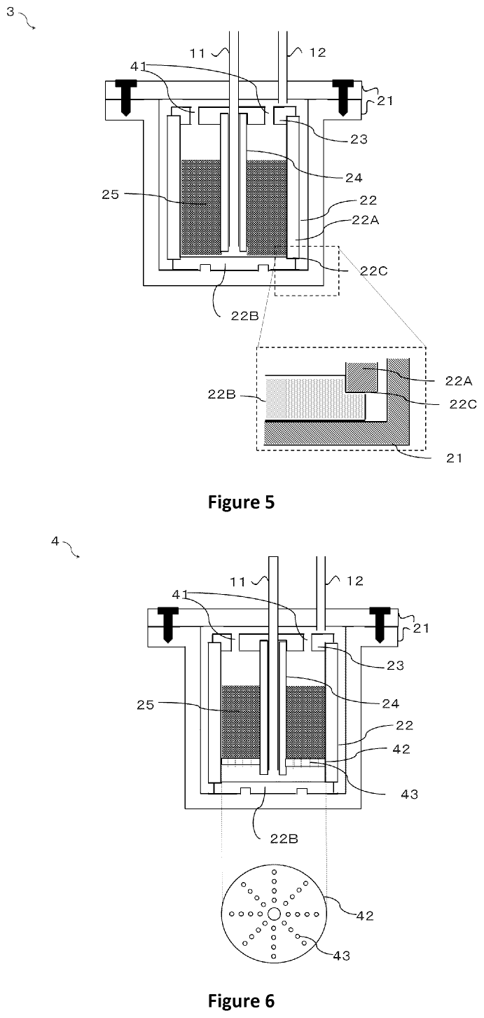

A solid material container 3 according to Embodiment 3 is described below, with reference to FIG. 5. Elements having the same reference numerals as in the solid material container 1 in Embodiment 1 and the solid material container 2 in Embodiment 2 perform the same functions, and therefore descriptions thereof are omitted.

The inner unit 22 of the solid material container 3 according to Embodiment 3 has inner unit side walls 22A and an inner unit bottom plate 22B, the inner unit side walls 22A having a bottom section fitting section 22C which removably fits onto the inner unit bottom plate 22B.

The inner unit side walls 22A and the inner unit bottom plate 22B are made separately, so machining is easier than when forming the inner unit 22 which is a single unit. In FIG. 5, steps are formed in the inner unit bottom plate 22B, and the inner unit side walls 22A are disposed so as to fit into the steps. The inner unit side walls 22A and the inner unit bottom plate 22B are fitted in the bottom section fitting section 22C, and therefore the solid material 25 filling the inner unit 22 does not leak out of the inner unit 22. The inner unit side walls 22A and the inner unit bottom plate 22B can be adhered together. Note that in FIG. 5, an enlarged view of the vicinity of the bottom section fitting section 22C is given. In order to make the enlarged view easier to see, the inner unit side walls 22A, the inner unit bottom plate 22B, and the outer unit 21 are grayed out or cross-hatched.

The shape of the fitting section 22C is not limited to a step shape. For example, recesses can be provided to the inner unit bottom plate 22B, and protrusions, which are the bottom section fitting section 22C, can be formed in the inner unit bottom plate 22B so as to fit into the recesses.

### Embodiment 4

A solid material container 4 according to Embodiment 4 is described below, with reference to FIG. 6. Elements having the same reference numerals as in the solid material containers 1-3 in Embodiments 1-3 perform the same functions, and therefore descriptions thereof are omitted.

An inner unit bottom plate 42 is disposed in the bottom section of the inner unit 22 of the solid material container 4 according to Embodiment 4, and the inner unit bottom plate 42 has one or more bottom ventilation sections 43 through which carrier gas flows.

The inner unit bottom plate 42 is disposed a predetermined distance away from the inner unit bottom plate 22B. The predetermined distance may be any distance allowing the carrier gas to flow therethrough, and may be between 1 mm and 30 mm, inclusive, for example. The inner unit bottom plate 42 may be affixed to the pipe cover unit 24 and/or the inner unit side walls 22A.

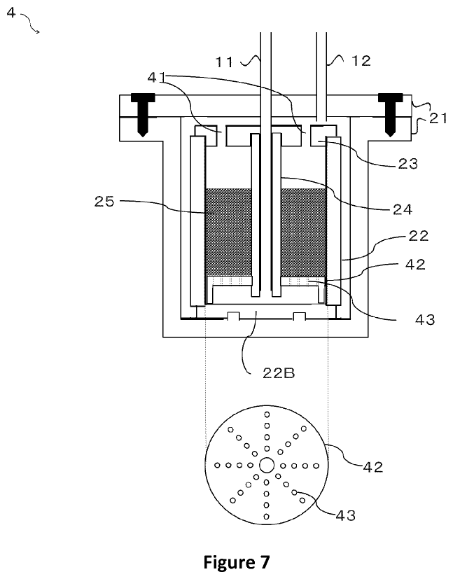

The inner unit bottom plate 42 may be a flat disk or it may be shaped like a Petri-dish with a raised surrounding edge. If the inner unit bottom plate 42 has a raised surrounding edge, the inner unit bottom plate 42 may be disposed such that the surrounding edge is disposed on the inner unit bottom plate 22B (see FIG. 7). The carrier gas introduced through the carrier gas introduction pipe 11 is fed to the inner unit bottom plate 22B through the outlet side of the carrier gas introduction pipe 11, passes through the bottom ventilation sections 43 of the inner unit bottom plate 42, and comes in contact with the solid material 25 filling the inner unit 22.

The bottom ventilation sections 43 need only have a shape allowing the carrier gas to pass therethrough, e.g., a slit shape, and one or more cylindrical holes may be disposed. The carrier gas fed out of the carrier gas introduction pipe 11 is dispersed by passing through the bottom ventilation sections 43, and can therefore come in contact with the solid material 25 more uniformly.

### Embodiment 5

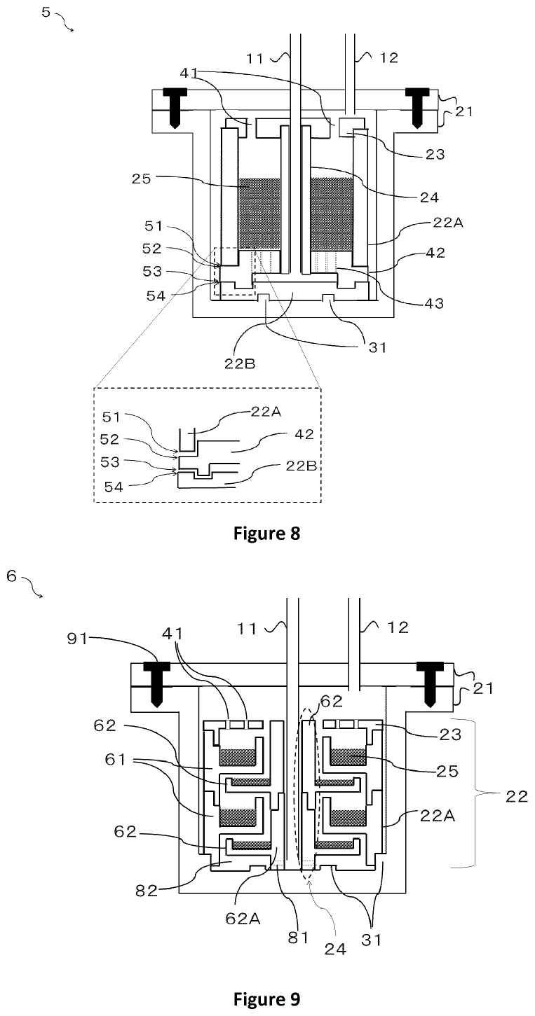

A solid material container 5 according to Embodiment 5 is described below, with reference to FIG. 8. Elements having the same reference numerals as in the solid material containers 1-4 in Embodiments 1-4 perform the same functions, and therefore descriptions thereof are omitted.

The inner unit side walls 22A of the solid material container 5 according to Embodiment 5 has a plate section top surface fitting section 51 which removably fits with a bottom plate top surface fitting section 52 disposed on the top surface of the inner unit bottom plate 42. The inner unit bottom plate 22B has a plate section bottom surface fitting section 54 which removably fits with a bottom plate bottom surface fitting section 53 which is disposed on the bottom surface of the inner unit bottom plate 42. An enlarged view of the vicinity of the bottom plate top surface fitting section 52 is shown at bottom left. Note that to make the enlarged view easier to see, spaces are included between the inner unit side walls 22A and the inner unit bottom plate 42 and between the inner unit bottom plate 42 and the inner unit bottom plate 22B, but in reality these sections are in contact with each other.

The bottom plate top surface fitting section 52 need only be formed so as to be removably fitted onto the plate section top surface fitting section 51. If the bottom plate top surface fitting section 52 is a protrusion, the plate section top surface fitting section 51 may be a recess. If the bottom plate top surface fitting section 52 is a recess, then the plate section top surface fitting section 51 may be a protrusion.

Similarly, the bottom plate bottom surface fitting section 54 need only be formed so as to be removably fitted onto the plate section bottom surface fitting section 53. If the bottom plate bottom surface fitting section 54 is a protrusion, the plate section bottom surface fitting section 53 may be a recess. If the bottom plate bottom surface fitting section 54 is a recess, then the plate section bottom surface fitting section 53 may be a protrusion.

In the solid material container 5 according to Embodiment 5, the carrier gas is introduced through the carrier gas introduction pipe 11, and is fed from the outlet end of the carrier gas introduction pipe 11 to the inner unit bottom plate 22B. The carrier gas passes through the bottom ventilation sections 43 of the inner unit bottom plate 42 and comes in contact with the solid material 25 filling the inner unit 22.

The inner unit side walls 22A, the inner unit bottom plate 42, and the pipe cover unit 24 are made out of a nonmetal material. Therefore the solid material 25 comes in contact with the inner unit side walls 22A which is made out of a nonmetal material, the inner unit bottom plate 42 which is made out of a nonmetal material, and the pipe cover unit 24 which is made out of a nonmetal material, but does not come in contact with members which are made out of metal. Accordingly, there is no metal contamination of the solid material 25 originating in metal members.

The carrier gas fed out of the carrier gas introduction pipe 11 is dispersed by passing through the bottom ventilation sections 43, and can therefore come in contact with the solid material 25 more uniformly.

The inner unit bottom plate 22B is fitted into and affixed to the outer unit 21 by the projections 31.

The inner unit bottom plate 42 is affixed to the inner unit bottom plate 22B by the plate section bottom surface fitting section 53 and the bottom plate bottom surface fitting section 54 being fitted together.

The inner unit side walls 22A is affixed to the inner unit bottom plate 42 by the plate section top surface fitting section 51 being fitted to the bottom plate top surface fitting section 52.

Therefore, in the outer unit 21, the inner unit side walls 22A, the pipe cover unit 24, the inner unit bottom plate 42, and the inner unit bottom plate 22B, which make up the inner unit 22, are fixed so as not to shift, preventing the solid material 25 from leaking out of the inner unit 22 into the outer unit 21.

### Embodiment 6

A solid material container 6 according to Embodiment 6 is described below, with reference mainly to FIG. 9. Elements having the same reference numerals as in the solid material containers 1-5 in Embodiments 1-5 perform the same functions, and therefore descriptions thereof are omitted.

The solid material container 6 according to Embodiment 6 has first trays 61 and second trays 62 which are disposed at fixed intervals vertically, are filled with the solid material 25, and at least those sections of which are in contact with the solid material 25 are made out of a nonmetal material.

The first trays 61 have an outer supporting section 61A on side edges (indicated by the cross-hatching in FIG. 11). The outer dimension of the first trays 61 is smaller than the inner dimension of the outer unit 21.

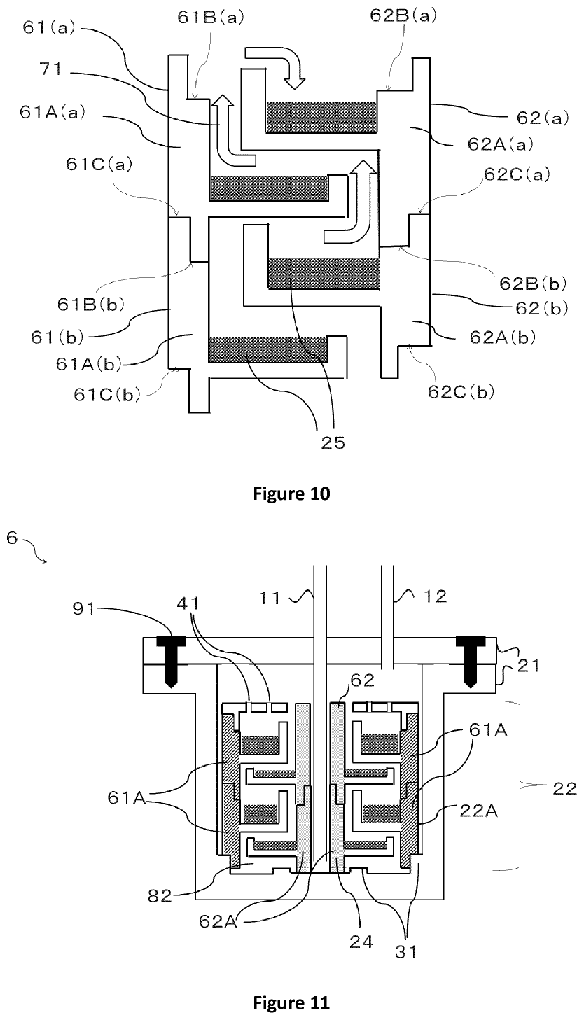

As shown in FIG. 11, the second trays 62 have an inner supporting section 62A (indicated by the shading in FIG. 11). The outer dimension of the second trays 62 is configured so as to be smaller than the outer dimension of the first trays 61 so as to form an outer flow path 71 (see FIG. 10).

The first trays 61 are disposed so as to form a vertical overlapping stack with the second trays 62.

FIG. 10 is an enlarged view of part of the left-hand side of the inner structure of FIG. 9.

A fluid flow path is provided between the first trays 61 and the second trays 62, along the outer flow path 71.

The first tray 61(a) disposed on top has an outer supporting section top fitting section 61B(a) provided on top of an outer supporting section 61A(a), and an outer supporting section bottom fitting section 61C(a) which is provided to the bottom of an outer supporting section 61A(a).

The first tray 61(b) disposed on the bottom has an outer supporting section top fitting section 61B(b) provided on top of an outer supporting section 61A(b), and an outer supporting section bottom fitting section 61C(b) which is provided to the bottom of an outer supporting section 61A(b).

The second tray 62(a) disposed on top has an inner supporting section top fitting section 62B(a) provided on top of an inner supporting section 62A(a), and an inner supporting section bottom fitting section 61C(a) which is provided to the bottom of the inner supporting section 62C(a).

The second tray 62(b) disposed on the bottom has an inner supporting section top fitting section 62B(b) provided on top of an inner supporting section 62A(b), and an inner supporting section bottom fitting section 62C(b) which is provided to the bottom of the inner supporting section 62A(b).

The outer supporting section top fitting section 61B(b) of the bottom first tray 61(b) is removably fitted so as to be stacked on the outer supporting section bottom fitting section 61C(a) of at least one of the vertically neighboring first trays 61(a) so as to be stacked. The shape of the outer support section top fitting section 61B(a) or 61B(b) may be a round or squared protrusion or recess. The outer supporting section bottom fitting section 61C(a) may be any shape which allows fitting with the shape of the outer supporting section top fitting section 61B(b), and may be a round or squared recess or protrusion.

The inner supporting section top fitting section 62B(b) of the bottom second tray 62(b) is removably fitted so as to be stacked on the inner supporting section bottom fitting section 62C(a) of at least one of the vertically neighboring second trays 62(a) so as to be stacked. The shape of the inner support section top fitting section 62B(a) or 62B(b) may be a circular or squared protrusion or recess. The inner supporting section bottom fitting section 62C(a) may be any shape which allows fitting with the shape of the inner supporting section top fitting section 62B(b), and may be a round or squared recess or protrusion.

The first trays 61 and the second trays 62 are alternatingly stacked from the bottom upward in this order: first tray 61(b), second tray 62(b), first tray 61(a), and second tray 62(a).

The bottommost second tray 62(b) is fixed in a predetermined location inside the outer unit 21 by being removably fitted to the projections 31 provided to the bottom surface of the outer unit 21 (see FIG. 9). The bottommost first tray 61(b) is fixed in a predetermined location inside the outer unit 21 by being removably fitted to another of the projections 31 provided to the surrounding edge of the bottom section of the outer unit 21 (see FIG. 9).

Gas flow in the solid material container 6 is described next, with reference mainly to FIG. 9.

The carrier gas is introduced into the solid material container 6 through the carrier gas introduction pipe 11. The carrier gas introduction pipe 11 is made out of metal but is covered by the pipe cover unit 24 formed by stacking the inner supporting sections 62A (see FIG. 11) of the second trays 62, and therefore the solid material 25 does not come in contact with the carrier gas introduction pipe 11 which is made out of metal.

The carrier gas supplied through the outlet end of the carrier gas introduction pipe 11 passes through a flow path 81 provided to the bottom of the inner supporting section 62A of the bottommost second tray 62, and enters a bottom space 82 of the bottommost second tray 62. Thereafter, the carrier gas passes through the outer flow path (71 in FIG. 10) and enters the second trays 62.

The carrier gas, which has passed over the solid material 25 filling the second trays 62 flows into the first trays 61 along the inner supporting section 62A of the second trays 62. The carrier gas which has flowed into the first trays 61 flows over the solid material 25 filling the first trays 61 and flows into the first trays 61 via the outer flow path 71. The carrier gas thus alternatingly passes through the first trays 61 and the second trays 62, through the upper ventilation sections 41, and is discharged through the solid material discharge pipe 12.

In FIG. 9, the lid unit 23 is removably fitted onto the outer support section bottom fitting section 61B (see FIG. 10) of the first trays 61. The center of the lid unit 23 has the upper ventilation sections 41 so as to form a fluid flow path with the inner supporting sections 62A (see FIG. 10) of the second trays 62.

The first trays 61 and the second trays 62 are disposed so as to be alternatingly stacked in a vertical direction. The first trays 61 and the second trays 62 may be disposed inside the outer unit 21 one at a time, or two or more sets may be disposed, one set being made up of one first tray 61 and one second tray 62. The number of the first trays 61 and the second trays 62 disposed inside the outer unit 21 may be any number according to the height of the outer unit 21, the characteristics of the solid material 25, the filling amount of the solid material 25, and so on. For example, there may be two each, three each, or four each of the first trays 61 and the second trays 62, and the number may be increased. There may be the same number of the first trays 61 and the second trays 62, or there may be one fewer of the second trays 62 than the first trays 61. The lid unit 23 is disposed on the first trays 61 or the second trays 62 disposed at the very top.

### EXAMPLES

### Example 1

Using the solid material container 4 according to Embodiment 4, a solid material product was made, using aluminum chloride as the solid material.

Three different types of material were used for the outer unit 21.

(1) Stainless steel (SUS 316L) (henceforth sometimes “SS”),

(2) Electropolished stainless steel (henceforth sometimes “EP”), or

(3) Fluorine-passivated and electropolished stainless steel (henceforth sometimes “passivated steel”).

Fluorine passivation is carried out by submerging electropolished stainless steel in a 0.5%-concentration solution of hydrogen fluoride at 20° C. for 30 min and washed with ultrapure water.

The following three types of materials were used for the inner unit side walls 22A, the inner unit bottom plate 22B, the inner unit bottom plate 42, and the pipe cover unit 24 making up the inner unit 21.

(A) A ceramic material (alumina, 99.5% purity),

(B) Stainless steel (SUS 316L) having an alumina surface layer on sections which come in contact with the solid material (henceforth sometimes “alumina covering”)

(C) Glass.

The alumina covering is formed by depositing alumina on the stainless steel to thickness of 200 nm using chemical vapor deposition (CVD).

The outer dimensions of the outer unit 21 in the solid material container 4 are a diameter of 200 mm and a height of 185 mm. The outer dimensions of the inner unit 22 are 186 mm and a height of 132 mm.

Aluminum chloride having a purity of 99.999% was used for the aluminum chloride. 1.1 kg of the aluminum chloride was filled.

Inside a glove box having a nitrogen atmosphere, the inner unit 22 contained in the outer unit 21 was filled with the aluminum chloride, and the lid unit 23 was closed. The outer unit 21 was sealed with the screws 91, and a solid material product in which the solid material container 4 was filled with aluminum chloride was obtained. The solid material product was removed from the glove box, and the solid material container was placed in a vehicle and transported 200 km to test the strength thereof. After transportation, the solid material product was heated to 150° C. for 14 days using an electric oven. After heating, the solid material produced was left to cool until the solid material container 4 reached 20° C., and then the contents were checked inside the glove box which was filled with a nitrogen atmosphere.

Table 1 gives the results of visual observation of damage (cracks) to various parts of the inner unit.

The aluminum chloride filling the inner unit was removed, and observations were made of any changes in the metal components in the aluminum chloride. Table 1 gives these results, too.

The metal components in the aluminum chloride were measured as follows.

1 g of the aluminum chloride was collected and dissolved with a solution in which hydrofluoric acid, nitric acid, and water were mixed at a 1:1:18 volume ratio. The metal was analyzed using an inductively coupled plasma mass spectrometer (ICP-MS) on the aluminum chloride solution. Table 1 gives the results. A PerkinElmer NexION 300S was used as the ICP-MS.

TABLE 1

| | | | | Metal Analysis Results | | |
|---|---|---|---|---|---|---|
| | Outer Unit | Inner Unit | Inner Unit | Fe | Cr | Ni |
| | Material | Material | Damage | (ppm) | (ppm) | (ppm) |
| Before use | — | — | — | 0.2 | 0.0 | 0.0 |
| Example 1-1 | SS | Alumina | No | 0.4 | 0.0 | 0.0 |
| Example 1-2 | SS | Alumina | No | 0.5 | 0.0 | 0.2 |
| | | covering | | | | |
| Example 1-3 | SS | Glass | No | 0.2 | 0.0 | 0.0 |
| Example 1-4 | EP | Alumina | No | 0.4 | 0.0 | 0.0 |
| Example 1-5 | EP | Alumina | No | 0.5 | 0.0 | 0.2 |
| | | covering | | | | |
| Example 1-6 | EP | Glass | No | 0.2 | 0.0 | 0.0 |
| Example 1-7 | Passivated | Alumina | No | 0.4 | 0.0 | 0.0 |
| | steel | | | | | |
| Example 1-8 | Passivated | Alumina | No | 0.5 | 0.0 | 0.2 |
| | steel | covering | | | | |
| Example 1-9 | Passivated | Glass | No | 0.2 | 0.0 | 0.0 |
| | steel | | | | | |
| Comparison ex. 1 | SS | SS | No | 37.0 | 1.0 | 4.1 |
| Comparison ex. 2 | — | Alumina | Yes | — | — | — |
| | | | (cracking) | | | |
| Comparison ex. 3 | — | Alumina | Yes | — | — | — |
| | | covering | (cracking) | | | |

When (1) the stainless steel (SUS 316), (2) the electropolished stainless steel, and (3) the fluorine-passivated and electropolished stainless steel, which are metal materials, were used for the outer unit, no cracking, splitting, or other damage were observed in the inner unit, whichever of the three nonmetal materials were used for the inner unit (alumina, alumina covering, or glass) (Examples 1-1 to 1-9). Accordingly, when a metal material is used for the outer unit and a nonmetal material is used for the inner unit, it can be said that there is sufficient strength for transportation and heating.

The three types of metal—iron (Fe), chrome (Cr), and nickel (Ni)—thought to have an adverse effect on formation of aluminum oxide thin films or aluminum nitride thin films in terms of metal impurities in the aluminum chloride were measured, and changes in the metal impurity content before and after heating in the solid material container were observed. The metal impurities in the aluminum chloride prior to filling the solid material were 0.2 ppm of iron, 0 ppm of chrome, and 0 ppm of nickel.

When glass was used in the inner unit, there were no changes in the metal impurity concentrations after heating, irrespective of the material of the outer unit (Examples 1-3, 1-6, and 1-9). It can therefore be said that when a glass inner unit is used, there was absolutely no metal contamination of the solid material.

When alumina, which is a ceramic material, was used in the inner unit, the iron increased from 0.2 ppm (before heating) to 0.4 ppm (after heating), irrespective of the material of the outer unit (Examples 1-1, 1-4, and 1-7). It can therefore be said that when the alumina inner unit was used, there was extremely little metal contamination of the solid material.

When the alumina covering was used in the inner unit, the iron grew from 0.2 ppm (before heating) to 0.5 ppm (after heating), and the Ni grew from 0 ppm (before heating) to 0.2 ppm (after heating), irrespective of the material of the outer unit (Examples 1-2, 1-5, and 1-8). It can therefore be said that when the alumina-covered inner unit was used, there was extremely little metal contamination of the solid material.

The reason there was slightly more metal contamination than when alumina or glass was used is possibly because visually unobservable cracks were caused by the heating, and contact occurred between the metal outer unit and the solid material through those cracks.

While the degree of metal contamination of the solid material differs depending on the material of the inner unit, the material of the outer unit was not observed to have any effect on metal contamination in these examples. However, depending on the characteristics of the solid material, it is more preferable to use EP, which can reduce the production of corrosion products, and yet more preferable to use EP and fluorine-passivated stainless steel.

### Comparison Example 1

We conducted a similar test as in Example 1 using stainless steel in the outer unit 21 and the inner unit 22.

No damage was seen in the inner unit when it was checked after heating.

On the other hand, when a metal analysis was done of the aluminum chloride after heating, high concentrations of the metal elements iron, chrome, and nickel, were detected, as shown in Table 1.

When a metal material is used in the inner unit 22, it was observed that metal contamination of the solid material present occurs.

### Comparison Example 2

An alumina inner unit 22 was made without using the outer unit 21. The alumina inner unit was placed in a vehicle and transported 200 km to check the strength thereof. When the inner unit was observed after transportation, visual confirmation was made of multiple cracks, as shown in Table 1.

This result confirms that inner units which are made out of a nonmetal material and are not contained in a metal outer unit have low strength and cannot withstand transportation.

### Comparison Example 3

An inner unit 22 covered in alumina was made without using the outer unit 21. The inner unit 22 was made by using CVD to cover the stainless steel SUS 316L with 200 nm of alumina.

The alumina-covered inner unit was placed in a vehicle and transported 200 km to check the strength thereof. When the inner unit was checked after transportation, no cracking was observed. However, as shown in Table 1, multiple cracks were observed in the covering alumina.

As shown in Table 1, no cracking was observed in Example 1-2, Example 1-5, and Example 1-8, but cracking was observed when the outer unit 21 was not used.

### Example 2

Using the solid material container 6 according to Embodiment 6, a solid material product was made, using aluminum chloride as the solid material.

A same test as in Example 1 was conducted, using the stainless steel outer unit 21 and alumina for the first trays 61, the second trays 62, and the lid unit 23 making up the inner unit 22.

The outer dimensions of the outer unit 21 in the solid material container 6 are a diameter of 200 mm and a height of 310 mm. The outer dimensions of the inner unit 22 are 191 mm and a height of 274 mm.

The tray outer diameter of the first trays 61 was 175 mm, the height of the inner supporting section 62A was 50 mm, and the depth of the trays was 15 mm.

The tray outer diameter of the second trays 62 was 189 mm, the height of the outer supporting section 61A was 50 mm, and the depth of the trays was 18 mm.

The trays were stacked vertically and alternatingly in the order first tray 61, second tray 62, first tray 61, and second tray 62 from the bottom inside the inner unit 22. Six of the first trays 61 and five of the second trays 62 were stacked. The first tray 61 was disposed at the top, and the lid unit 23 was disposed on that topmost first tray 61.

Aluminum chloride having a purity of 99.999% made by Konjundo Chemical Laboratory Co., Ltd., was used for the aluminum chloride. 6 kg of the aluminum chloride was filled.

As in Example 1, after heating to 150° C. for 14 days, the first trays 61, the second trays 62, and the lid unit 23 were visually observed, and no damage was observed.

When the aluminum chloride after heating was analyzed, the iron grew from 0.2 ppm (before heating) to 0.4 ppm (after heating), but no changes were seen in the chrome or nickel concentrations.

These results show that there was sufficient strength in Embodiment 6, and that the metal contamination was successfully minimized to a low level.

### Example 3

Using the solid material container 4 according to Embodiment 4, a solid material product was made, using aluminum chloride as the solid material. The following four materials were used for the inner unit 22.

(a) A material in which the stainless steel SUS 316L was covered in 500 nm of SiO₂

(b) A material in which the stainless steel SUS 316L was covered in 20 nm of alumina

(c) A material in which the stainless steel SUS 316L was covered in 50 nm of alumina

(d) A material in which the stainless steel SUS 316L was covered in 100 nm of alumina

The inner unit 22 was filled with 1 kg of the aluminum chloride and heated to 170° C. for five days. The surface of the inner unit 22 after heating was observed using an optical microscope.

The observations using an optical microscope showed that with (a) and (d) there were almost no changes in the condition of the metal surfaces before filling the aluminum chloride and after filling and heating.

With (c), the surface was observed to be slightly rougher after filling and heating.

With (d), the surface was rougher after filling and heating, but no major discoloration or rust was observed.

### Comparison Example 4

Using the solid material container 4 according to Embodiment 4, a solid material product was made, using aluminum chloride as the solid material, and the same test as in Example 3 was carried out. Uncovered stainless steel SUS 316L was used for the inner unit 22.

In Comparison Example 2, the surface of the stainless steel after filling with aluminum chloride and heating to 170° C. for 5 days was significantly rougher, and discoloration and rust were observed on the surface.

### Example 4

An aluminum oxide film was formed on a semiconductor substrate using a solid material product filled with aluminum chloride as the solid material, using the solid material container 6 (having the stainless steel outer unit 21 and the inner unit 22 having the alumna-covered first trays 61 and the alumina-covered second trays 62) according to Embodiment 6 and the container (the container in which the alumina inner unit 22 was disposed inside the stainless steel outer unit 21) used in Example 1-1.

These two containers were heated to 120° C., and argon gas was caused to flow therethrough at a flow rate of 500 SCCM as the carrier gas, thereby supplying aluminum chloride vapor over the semiconductor substrate. Ozone was used as an oxidizing agent, and the aluminum oxide film was formed on the silicon substrate using ALD to a thickness of 3 mm.

Table 2 shows the results of a TXRF (total reflection X-ray fluorescence) analysis of the metal components (chrome, iron, and nickel) on the aluminum oxide film which resulted.

TABLE 2

| | | | | Analysis results | |
|---|---|---|---|---|---|
| | Outer unit | Inner unit | Metal | (atoms/cm²) | |
| Container type | material | material | Cr | Fe | Ni |
| Embodiment 6 | Stainless steel | Alumina | 8.00 × 10¹⁰ | 4.00 × 10¹⁰ | 2.00 × 10¹¹ |
| | (SUS 316L) | covering | | | |
| Example 1-1 | Stainless steel | Alumina | 6.20 × 10⁹ | 5.50 × 10⁹ | 3.40 × 10⁹ |
| | (SUS316L) | | or less | | or less |

The results of Example 3 and Comparison Example 4 confirmed that the material in which the stainless steel was covered in SiO₂ or alumina was suitable as the nonmetal material for the solid material container, and in particular that the material in which the stainless steel was covered with the alumina to a thickness of 100 nm was suitable. Furthermore, when the solid material container in which the outer and inner units were both made out of stainless steel was filled with the aluminum chloride and an aluminum oxide film was made as in Example 4, at least 1.00×10¹¹ atoms/cm² were detected of chrome, iron, and nickel in the aluminum oxide film which resulted.

These results indicate that metal impurities were observably reduced in the resulting films using containers filled with the solid material when a nonmetal material was used in the inner unit, which comes in contact with the solid material, and nonmetal materials were used the first trays, the second trays, and the lid unit.

### EXPLANATION OF THE REFERENCE NUMERALS

1. Solid material container
2. Solid material container
3. Solid material container
4. Solid material container
5. Solid material container
6. Solid material container
11. Carrier gas introduction pipe
12. Solid material discharge pipe
21. Outer unit
22. Inner unit
22A. Inner unit side walls
22B. Inner unit bottom section
22C. Bottom section fitting section
23. Lid unit
23A. Raised surrounding edge
23B. Bottom edge
24. Pipe cover unit
25. Solid material
31. Projections
32. Inner unit fitting section
33. Lid unit fitting section
41. Upper ventilation sections
42. Inner unit bottom plate
43. Bottom ventilation sections
51. Plate section top surface fitting section
52. Bottom plate top surface fitting section
53. Plate section bottom surface fitting section
54. Bottom plate bottom surface fitting section
61. First trays
61(a). First tray
61(b). First tray
61A. Outer supporting section
61A(a). Outer supporting section
61A(b). Outer supporting section
61B. Outer supporting section top fitting section
61B(a). Outer supporting section top fitting section
61B(b). Outer supporting section top fitting section
61C. Outer supporting section bottom fitting section
61C(a). Outer supporting section bottom fitting section
61C(b). Outer supporting section bottom fitting section
62. Second trays
62(a). Second trays
62(b). Second trays
62A. Inner supporting section
62A(a). Inner supporting section
62A(b). Inner supporting section
62B. Inner supporting section top fitting section
62B(a). Inner supporting section top fitting section
62B(b). Inner supporting section top fitting section
62C. Inner supporting section bottom fitting section
62C(a). Inner supporting section bottom fitting section
62C(b). Inner supporting section bottom fitting section
71. Outer flow path
81. Flow path
82. Bottom space
91. Screws

While the invention has been described in conjunction with specific embodiments thereof, it is evident that many alternatives, modifications, and variations will be apparent to those skilled in the art in light of the foregoing description. Accordingly, it is intended to embrace all such alternatives, modifications, and variations as fall within the spirit and broad scope of the appended claims. The present invention may suitably comprise, consist or consist essentially of the elements disclosed and may be practiced in the absence of an element not disclosed. Furthermore, if there is language referring to order, such as first and second, it should be understood in an exemplary sense and not in a limiting sense. For example, it can be recognized by those skilled in the art that certain steps can be combined into a single step.

The singular forms “a”, “an” and “the” include plural referents, unless the context clearly dictates otherwise.

“Comprising” in a claim is an open transitional term which means the subsequently identified claim elements are a nonexclusive listing (i.e., anything else may be additionally included and remain within the scope of “comprising”). “Comprising” as used herein may be replaced by the more limited transitional terms “consisting essentially of” and “consisting of” unless otherwise indicated herein.

“Providing” in a claim is defined to mean furnishing, supplying, making available, or preparing something. The step may be performed by any actor in the absence of express language in the claim to the contrary.

Optional or optionally means that the subsequently described event or circumstances may or may not occur. The description includes instances where the event or circumstance occurs and instances where it does not occur.

Ranges may be expressed herein as from about one particular value, and/or to about another particular value. When such a range is expressed, it is to be understood that another embodiment is from the one particular value and/or to the other particular value, along with all combinations within said range.

All references identified herein are each hereby incorporated by reference into this application in their entireties, as well as for the specific information for which each is cited.

1. A solid material container for gasifying and supplying a solid material contained therein, comprising a solid material discharge pipe that discharges a vapor of the solid material out of the solid material container, a metal outer unit, an inner unit which is filled with the solid material and in which at least those sections in contact with the solid material are made out of a nonmetal material, and a lid unit which is disposed on top of the inner unit, and in which at least those sections in contact with the solid material are made out of a nonmetal material, wherein the inner unit and the lid unit are contained inside the outer unit.

2. The solid material container as claimed in claim 1, wherein protrusions are formed on the inside of the outer unit, and the bottom of the inner unit has an inner unit fitting section which removably fits into the outer unit on the projections.

3. The solid material container as claimed in claim 1, wherein the lid unit has at least one upper ventilation section through which the vapor of the solid material passes.

4. The solid material container of claim 1, wherein the lid unit has a lid fitting section which removably fits onto the top of the inner unit.

5. The solid material container of claim 1, wherein the inner unit has inner unit side walls and an inner unit bottom section, and the inner unit side walls have a bottom section fitting section which removably fits onto the inner unit bottom section.

6. The solid material container claim 1, wherein an inner section bottom plate is disposed in the inner unit bottom section, and the inner unit bottom plate has one or more bottom ventilation sections through which a carrier gas passes.

7. The solid material container as claimed in claim 6, wherein the inner unit side walls have plate section top surface fitting sections which removably fit onto a bottom plate top surface section disposed on the top surface of the inner unit bottom plate, and the inner unit bottom section has a plate section bottom surface fitting section which removably fits with a bottom plate bottom surface fitting section disposed on a bottom surface of the inner unit bottom plate.

8. The solid material container of claim 1, wherein the inner unit is configured by a plurality of trays which are disposed at fixed intervals vertically, which are filled with the solid material, and at least those sections thereof which come in contact with the solid material are made out of a nonmetal material.

9. The solid material container as claimed in claim 8, wherein the plurality of trays comprise at least one first tray which has an outer supporting section on side edges thereof and is smaller than the inner dimension of the outer unit, and at least one second tray, which has an inner supporting section in a central section thereof and is smaller than the outer dimension of the first tray for forming an outer flow path, wherein the first tray is disposed so as to form an overlapping vertical stack with a neighboring second tray, and fluid flow path is provided between the first tray and the second tray passing through an outer flow path.

10. The solid material container according to claim 9, wherein the first tray has an outer supporting section top fitting section provided to the top of the outer supporting section, and an outer supporting section bottom fitting section provided to the bottom of the outer supporting section, the second tray has an inner supporting section top fitting section provided to the top of the inner supporting section, and an inner supporting section bottom fitting section provided to the bottom of the inner supporting section, the outer supporting section top fitting section of at least one of the first trays is removably fitted so as to be stacked on the outer supporting section bottom fitting section of at least one of the vertically neighboring first trays, and the inner supporting section top fitting section of at least one of the first trays is removably fitted so as to be stacked on the inner supporting section bottom fitting section of at least one of the vertically neighboring first trays.

11. The solid material container of claim 1, wherein the nonmetal material is at least one material selected from the group consisting of ceramic materials, glass, polymer materials, metal nitride containing materials, metal oxide containing materials, carbon containing materials, and quartz.

12. The solid material container of claim 11, wherein the nonmetal material is the ceramic material which comprises at least one material selected from the group consisting of alumina, zirconia, barium titanate, hydroxyapatite, silicon carbide, silicon nitride, aluminum nitride, titanium nitride, titanium oxide, yttrium oxide, and fluorite.

13. The solid material container of claim 1, wherein the inner unit, the lid unit, the inner unit side walls, the inner unit bottom section, the inner unit bottom plate, and/or the trays have a surface layer made out of a nonmetal material on at least part of the surface of a metal material.

14. A solid material product in which a solid material fills the solid material container as claimed in claim 1.
